(19) United States
(12) Patent Application Publication
(10) Pub. No.: US 2024/0006786 A1
(43) Pub. Date: Jan. 4, 2024

(54) COMPOSITE PRINTED CIRCUIT BOARDS AND DEVICES

(71) Applicant: Intel Corporation, Santa Clara, CA (US)

(72) Inventors: Howe Yin LOO, Bayan Lepas (MY); Tin Poay CHUAH, Bayan Lepas (MY); Jenny Shio Yin ONG, Bayan Lepas (MY); Chee Min LOH, Bayan Lepas (MY); Bok Eng CHEAH, Gelugor (MY); Jackson Chung Peng KONG, Tanjung Tokong (MY); Seok Ling LIM, Kulim Kedah (MY); Kooi Chi OOI, Gelugor (MY)

(21) Appl. No.: 17/857,051

(22) Filed: Jul. 4, 2022

(51) Int. Cl. H01R 12/57; H01R 12/70

(52) U.S. Cl. CPC H01R 12/57; H01R 12/7082; H01R 12/707

(57) ABSTRACT

The present disclosure is directed to a printed circuit board having a composite upper surface with a first section of a first-type of printed circuit board and a second section of a second-type of printed circuit board, for which the first section of the first-type of printed circuit board and the second section of the second-type of printed circuit board are coupled, respectively, to at least one device that is configured to abridge the first and second sections of the composite upper surface. In an aspect, the second-type of printed circuit board is configured to be embedded in the first-type of printed circuit board and the first-type of printed circuit board is configured to receive the second-type of printed circuit board.

### BACKGROUND

In integrated circuit design and fabrication, the need to improve performance and lower costs are constant challenges. For example, mobile device platforms widely use Type-III printed circuit boards (PCB) as vertical stack-ups to maintain lower costs. A Type-III PCB is a multilayer circuit board having two or more layers with plated through-holes vias. However, the memory devices will typically need to be placed further away from the central processing unit (CPU) when using Type-III PCB. The interconnect configuration for the input-outputs of the memory devices will break out on the PCB surface layers before transitioning to inner routing layers using plated through hole (PTH) vias before eventually being coupled with the CPU.

Electrical signal degradations due to loss from channel impedance discontinuities, and/or signal reflections commonly occur with Type-III PCBs. For example, a PTH via may have an “unused” stub, which is a conductive portion of the PTH that is orthogonal to the lateral traces. The unused stub or un-terminated transmission line may cause significant signal degradation around its resonant frequency (determined by the quarter wavelength of the structure). The longer the stub, the larger the impedance discontinuity and significant signal attenuation loss, which may reduce system memory performance. Approaches to mitigating signal reflection due to PTH stubs include backdrilling of PTH vias or the use of split core PCB designs to minimize the impact of PTH stubs.

The use of higher-cost Type-IV PCBs having high density interconnects (HDI) that use blind, buried, or micro-via technologies to form the vertical interconnection to facilitate signal routing at inner layers do not have concerns caused by PTH stubs. The use of the HDI PCBs allows for via-in-pad designs, thus enabling the memory parts to be coupled to the CPU through a less distorted channel, as memory I/O may have a breakout inside the pin field region using PCB inner layer. The use of HDI PCBs also creates an opportunity for higher memory margin due to shorter memory trace length and stubless interconnects for the memory trace. An implementation may use a Type IV PCB as a separate translator module board for the processor chip and memory devices, while a Type III PCB may be used as a motherboard. However, in addition to a higher bill of materials, a translator module implementation may not scale across different board designs and may impact the overall z-height while causing challenges to PCB assembly.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIGS. 1 and 1A show cross-section and top views, respectively, of an exemplary semiconductor assembly with a printed circuit board according to an aspect of the present disclosure;

FIGS. 2, 2A, and 2B show cross-section, top and bottom views, respectively, of another exemplary semiconductor assembly with a printed circuit board according to an aspect of the present disclosure;

FIG. 3 shows a ball array map according to an aspect of the present disclosure;

FIGS. 4A through 4D show exemplary method steps for embedding a Type-IV printed circuit board in a Type-III printed circuit board according to an aspect of the present disclosure;

FIGS. 5 and 5A show cross-section and top views, respectively, of an exemplary semiconductor assembly with a printed circuit board with a Type IV printed circuit board embedded in a recess formed in a Type III printed circuit board according to an aspect of the present disclosure;

FIGS. 6 and 6A show cross-section and top views, respectively, of another exemplary semiconductor assembly with a printed circuit board with two Type IV printed circuit boards embedded in their respective recesses formed in a Type III printed circuit board according to an aspect of the present disclosure;

FIGS. 7A through 7E show exemplary method steps for embedding a Type-IV printed circuit board in a recess formed in a Type-III printed circuit board according to another aspect of the present disclosure; and

FIG. 8 shows a simplified flow diagram for an exemplary method according to an aspect of the present disclosure.

### DETAILED DESCRIPTION

The following detailed description refers to the accompanying drawings that show, by way of illustration, specific details, and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects can be combined with one or more other aspects to form new aspects.

The present disclosure is directed to a composite or heterogeneous printed circuit board, as well as semiconductor assemblies made using such composite printed circuit boards, that provides an upper surface with a first section of a first-type of printed circuit board and a second section of a second-type of printed circuit board. The second-type of printed circuit board is configured to be embedded in an opening or a recess in the first-type of printed circuit board.

In another aspect, the present disclosure is also directed to a semiconductor assembly having a composite printed circuit board with a first section of a first-type of printed circuit board and a second section of a second-type of printed circuit board. Such a semiconductor assembly may have at least one device that is configured to abridge the first and second sections of the upper surface and electrically couple the first-type of printed circuit board with the second-type of printed circuit board.

In particular, the present composite printed circuit board (PCB) provides a planar mainboard or motherboard with two different PCB technologies—a smaller Type 4 PCB as an embedded translator module with, for example, the memory routings between a system-on-chip or SOC and one or more memory chips to optimize the performance of these connections, i.e., signaling pathways, while the Type III sections of the mainboard may provide the remainder of the mainboard connections, such I/O connections, power, etc. The memory chips may, for example, include a dynamic random access memory (DRAM) such as a 5^{th} Generation Double Data Rate (DDR5) memory, a 6^{th} Generation Double Data Rate (DDR6) memory, a 5^{th} Generation Low-Power Double Data Rate (LPDDR5) memory, or a 6^{th} Generation Low-Power Double Data Rate (LPDDR6) memory.

A technical advantage of the present disclosure includes providing improved signal integrity by reducing channel impedance discontinuities, and signal reflections from un-terminated transmission lines that are found with conventional Type-III PCB. The multi-reflection noises associated with Type-3 PCB may be eliminated with the absence of open-ended PTH stubs in the Type-IV sections, therefore enhancing high-speed signaling margins.

Another technical advantage of the present disclosure includes improved signal integrity performance by using a segregated routings approach; for example, high-density signal routings between devices through Type-IV HDI PCB and power delivery to the devices through the use of reduced effective self-resistance connections (i.e., larger interconnects and/or planes) available in Type-III PCB. In an aspect, the memory trace routings on the embedded thinner Type-IV PCB provide micro-via technology for improved signal integrity of the memory interconnects. The LPDDR5 performance, for example, may be improved by reducing the margin loss in the vertical interconnects and/or shorter signal current return path.

An additional technical advantage of the present disclosure includes package and platform miniaturization through a size reduction in the motherboard size, e.g., a reduction in the core area (SOC and memory) with a compact embedded Type-IV HDI module in a planar or substantially planar configuration with a larger Type-III motherboard. The size reduction may include a miniaturized Type-4 HDI PCB footprint, high-density I/O routing through the Type-IV PCB, and reduced package form-factor through ball grid array pitch-scaling. These reductions will translate to overall package x, y, and z-dimensions reduction.

To more readily understand and put into practical effect the present composite PCB motherboard and methods, which may be used for semiconductor assemblies, particular aspects will now be described by way of examples provided in the drawings that are not intended as limitations. The advantages and features of the aspects herein disclosed will be apparent through reference to the following descriptions relating to the accompanying drawings. Furthermore, it is to be understood that the features of the various aspects described herein are not mutually exclusive and can exist in various combinations and permutations. For the sake of brevity, duplicate descriptions of features and properties may be omitted.

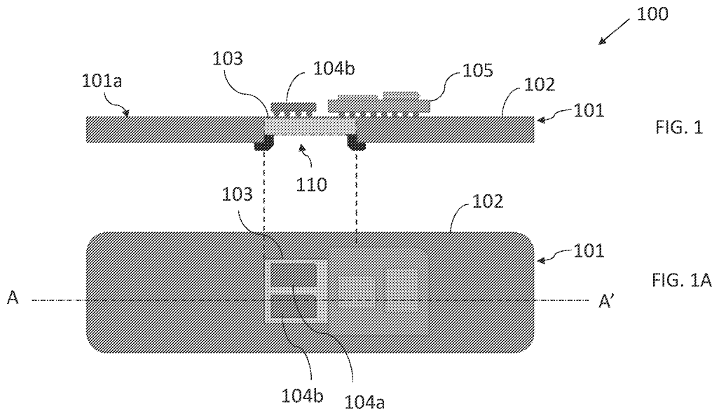

FIGS. 1 and 1A show cross-section and top views, respectively, of an exemplary semiconductor assembly 100 with a composite printed circuit board 101 according to an aspect of the present disclosure. FIG. 1 shows a cross-section view along the section line A-A′ shown in FIG. 1A. In this aspect, the composite printed circuit board 101 includes a first section of first type PCB 102 and a second section of second type PCB 103 that form a composite upper surface 101a. The first type PCB 102 may be a Type-III PCB as the mainboard or motherboard and the second type PCB 103 may be a Type-IV PCB, which may be an embeddable section or translator module placed in an opening 110. The use of a small section of Type-IV PCB within a larger mainboard of Type-III PCB may be able to lower the cost of the bill of materials. In another aspect, the second type PCB 103 may be a molded interconnect layer or substrate, which also provides embedded copper trace technology having finer lines and spaces for high density interconnects and a smaller form factor.

As shown in FIGS. 1 and 1A, the semiconductor assembly 100 may have a plurality of devices, which may include a system-on-chip (SOC) 105 and memory devices 104a and 104b, which may include DRAM devices such as DDR5 memory devices, DDR6 memory devices, LPDDR5 devices or LPDDR6 memory devices. Although not shown, it should be understood that other components/devices may be provided to complete the semiconductor assembly 100. In this aspect, the SOC 105 abridges sections 102 and 103 of the composite printed circuit board 101, while the memory devices 104a and 104b may have footprints that are placed fully on the second section 103 of the composite printed circuit board 101. According to an aspect of the present disclosure, the memory trace routings on the embedded thinner Type-IV PCB provide micro-via technology for improved signal integrity for the memory interconnects.

In another aspect, the use of an embedded Type-IV PCB may provide a reduction in the z-direction dimension of a semiconductor assembly when compared with use of module in board (MOB) designs; for example, eliminating the need for stacking an HDI PCB on top of a Type-III PCB motherboard may reduce the z-direction dimension by approximately 0.56 mm. It should be understood that an overall reduction of the z-direction dimension will depend on the number of MOBs in a particular design.

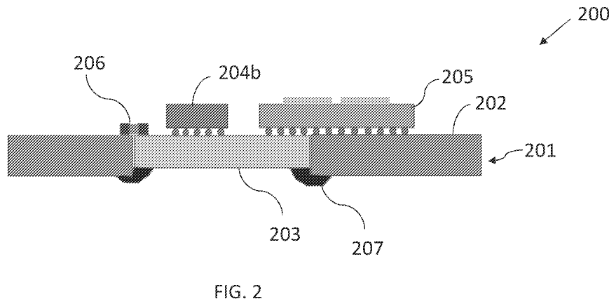

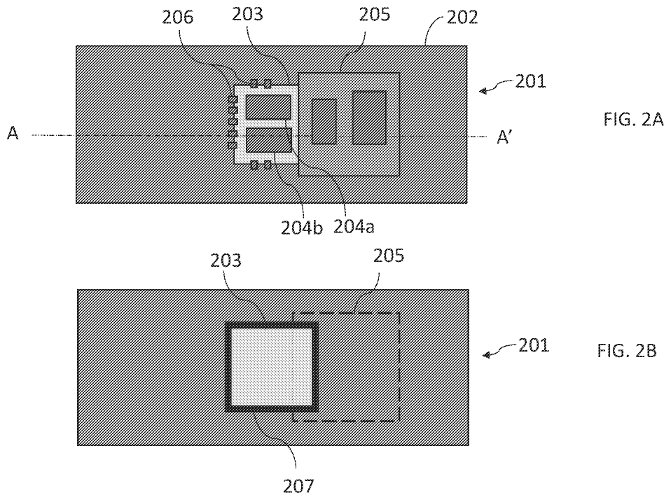

FIGS. 2, 2A, and 2B show cross-section, top and bottom views, respectively, of another exemplary semiconductor assembly 200 with a composite printed circuit board 201 according to an aspect of the present disclosure. FIG. 2 shows a cross-section view along the section line A-A′ shown in FIG. 2A. In this aspect, the composite printed circuit board 201 includes a first section of first type PCB 202 and a second section of second type PCB 203. The first type PCB 202 may be a Type-III PCB as the mainboard or motherboard and the second type PCB 203 may be a Type-IV PCB, which may be an embeddable section or translator module placed in an opening 110.

As shown in FIGS. 2 and 2A, the semiconductor assembly 200 may have a plurality of devices, which may include a system-on-chip (SOC) 205, memory devices 204a and 204b, and a plurality of zero-ohm resistors 206. Although not shown, it should be understood that other components/devices may be provided to complete the semiconductor assembly 200. In this aspect, the SOC 205 and the zero-ohm resistors abridge sections 202 and 203 of the composite printed circuit board 201, while the memory devices 204a and 204b may have footprints that are placed fully on the second section 203 of the composite printed circuit board 201.

Further to this aspect, the zero-ohm resistors 206 may be used as interconnects between sections 202 and 203 of the composite printed circuit board 201. In an aspect, the zero-ohm resistors 206 may provide, for example, power connections to memory voltage regulators for the memory devices 204a and 204b. The use of a zero-ohm resistor may typically be in place of a wire link or cable and may be inserted automatically by PCB assembly robots. The present semiconductor assemblies may use zero-ohm resistors to couple different types of PCBs and, in addition, enable flexibility regarding the size and placement of such PCBs.

In another aspect, as shown in FIGS. 2 and 2B, the first section of first type PCB 202 and the second section of second type PCB 203 of the composite printed circuit board 201 may be held together by an adhesive material 207, such as epoxy. As shown in FIG. 2B, the adhesive material 207 may be placed along the entire boundary between the first type PCB 202 and the second type PCB 203.

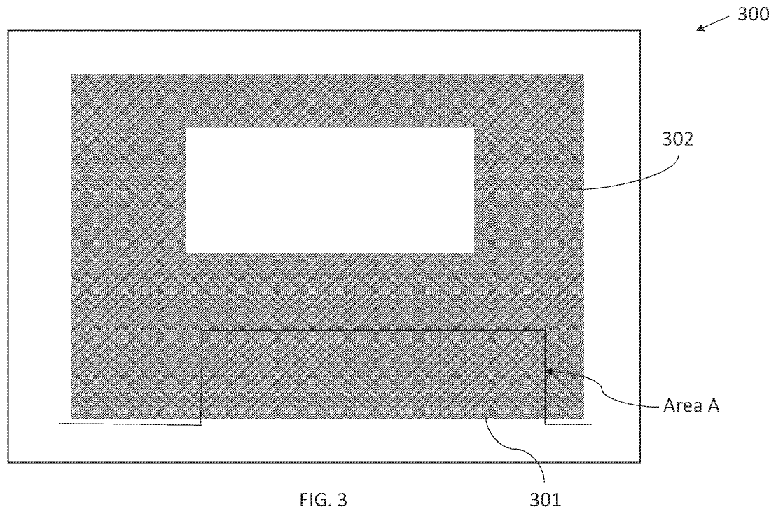

FIG. 3 shows a ball array map 300 according to an aspect of the present disclosure. In an aspect, the ball array map 300 provides for the placement of the memory solder balls 301 in a separate Area A, which is shown in a south-center area of the ball array, to enable a SOC ball grid to have sufficient space for memory traces to break out on the memory region and allow connection of the SOC to the memory(s) on a second section or translator module with a second type PCB (e.g., Type-IV PCB). Such a configuration may allow a footprint reduction for a SOC package, for example, the SOC 205 shown in FIGS. 2, 2A and 2B, through reduced solder ball spacings and with ground balls placed around the edge of the memory device balls.

In addition, a ball array map 300 of the present disclosure may permit a larger ball pitch outside of the Area A. In an aspect, the memory solder balls 301 may include a first pitch geometry ranging from 0.3 mm to 0.5 mm. In an aspect, the SOC ball array 300 may include a plurality of solder balls 302 having a second pitch geometry greater than the first pitch geometry ranging from 0.5 mm to 1.0 mm.

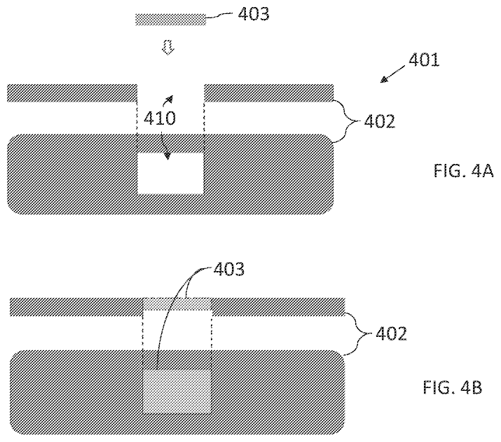

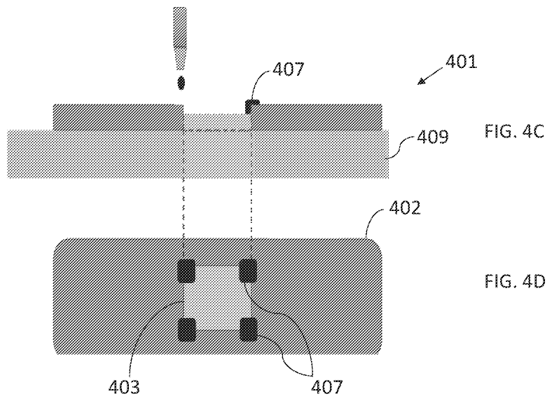

FIGS. 4A through 4D show exemplary method steps for forming a composite printed circuit board 401 by embedding a section of a second type or Type-IV PCB 403 in a first type or Type-III PCB 402 motherboard according to an aspect of the present disclosure. As shown in FIG. 4A, the Type-III PCB 402 may be configured to have an opening 410 and the Type-IV PCB 403 may be configured to be positioned in the opening 410. As shown in FIG. 4B, in an aspect, the Type-IV PCB 403 may be thinner than the Type-III PCB 402 and the two sections form a co-planar upper surface of the composite printed circuit board 401.

As shown in FIG. 4C, the composite printed circuit board 401 may be inverted and its upper surface placed on a flat working platform 409. An adhesive material 407 may be applied to attach/bond the section of second type PCB 403 to the first type PCB 402. As shown in FIG. 4D, the adhesive material 407 may be placed at the corners of the boundary between the first type PCB 402 and the second type PCB 403.

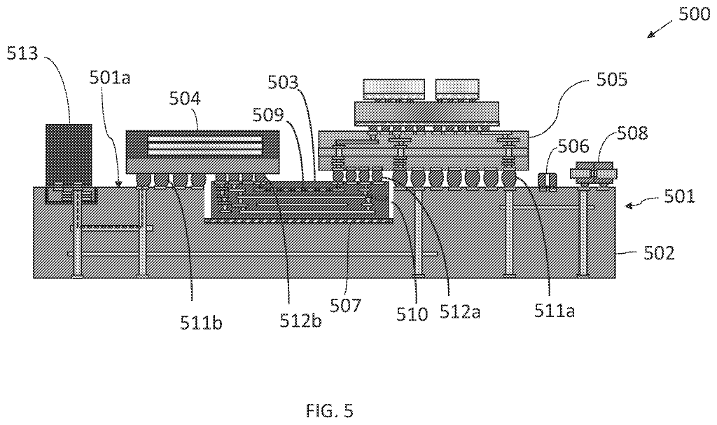

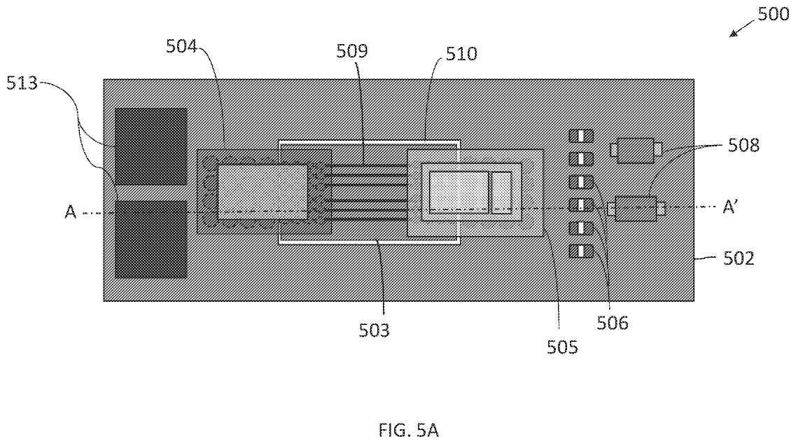

FIGS. 5 and 5A show cross-section and top views, respectively, of an exemplary semiconductor assembly 500 with a composite or heterogeneous printed circuit board 501 with a second type PCB embedded in a recess formed in a first type PCB according to an aspect of the present disclosure. FIG. 5 shows a cross-section view along the section line A-A′ shown in FIG. 5A. In this aspect, the composite printed circuit board 501 includes a first section of first type PCB 502 and a second section of second type PCB 503 to form a composite upper surface 501a. The first type PCB 502 may be a Type-III PCB as the mainboard or motherboard and the second type PCB 503 may be a Type-IV PCB, which may be an embeddable section or translator module placed in a recess 510. In an aspect, the recess 510 may have a depth that allows the second type PCB 503 to be co-planar with the first type PCB 502, or as shown in FIG. 5, positions the second type PCB 503 to be elevated higher than a top surface of the first type PCB 502 forming a step therebetween.

In an aspect, the first type PCB 502 motherboard may include a first metal layer stack-up having a plurality of routing layers extending between the top surface and a bottom surface of the first type PCB 502, and the routing layers are coupled through a plurality of plated through hole (PTH) vias extending from the top surface through to the bottom surface, as well as other conventional features of Type-III PCBs. In an aspect, the first PCB 502 may have a thickness ranging from approximately 0.8 mm to 1 mm.

In another aspect, the second type PCB 503 may be a molded interconnect layer or substrate, which also provides embedded copper trace technology having finer lines and spaces for high-density interconnects and a smaller form factor. In a further aspect, the second type PCB 503 may be made of a material such as a bismaleimide triazine (BT) epoxy layer with reinforced fiber glasses or one or more layers of epoxy mold compound composites.

In an aspect, the second type PCB 503 may include a metal layer stack-up having a plurality of routing layers extending between a top surface and a bottom surface of the second type PCB 503, and the routing layers are coupled through a plurality of vertical micro-vias or lasered vias, as well as other conventional features of Type-IV PCBs. In a further aspect, the second type PCB 503 may have a thickness ranging approximately from 100 μm to 600 μm. In an aspect, an adhesive material 507 may be applied at a bottom surface of the recess 510 to attach/bond the section of second type PCB 503 to the first type PCB 502.

As shown in FIG. 5, the semiconductor assembly 500 may have a plurality of devices that are coupled to the composite upper surface 501a, which may include a first device 505 (e.g., a semiconductor package having a central processing unit (CPU), system on chip (SOC), controller hub chiplets, a radio frequency integrated circuit (RFIC), a deep learning processor (DLP), a graphic processing unit (GPU), a neural network processor (NNP) and/or an I/O tile), a second device 504, (e.g., one or more dynamic random access memory (DRAM) devices such as a 5^{th} Generation Double Data Rate (DDR5) memory device, a 6^{th} Generation Double Data Rate (DDR6) memory device, a 5^{th} Generation Low-Power Double Data Rate (LPDDR5) memory device, or a 6^{th} Generation Low-Power Double Data Rate (LPDDR6) memory device), passive components 506 (e.g., resistors, capacitors, and coils), power components 513 (e.g., voltage regulators), and connectors 508. Although not shown, it should be understood that other components/devices may be provided to complete the semiconductor assembly 500. In an aspect, the first and second devices 505 and 504, respectively, may be configured to abridge and couple the sections 502 and 503 of the composite printed circuit board 501.

In another aspect, as shown in FIG. 5, the first device 505 may have solder balls 511a for bonding and coupling with the Type-III PCB 502 and solder balls 512a for bonding and coupling with the Type-IV PCB 503, and the second device 504 may have solder balls 511b for bonding and coupling with the Type-III PCB 502 and solder balls 512b for bonding and coupling with the Type-IV PCB 503. As also shown in FIG. 5, by way of the solder balls 512a and 512b, respectively, the first device 505 may be coupled to the second device 504 by a signal connection 509 in the Type-IV PCB 503.

In an aspect, the solder balls 511a and 511b, with identical diameters ranging from approximately 250 μm to 700 μm, will be larger than solder balls 512a and 512b, with identical diameters ranging from approximately 100 μm to 250 μm, when the Type-IV PCB 503 is positioned elevated higher than the Type-III PCB 502. In another aspect, the solder balls 511a and 511b may include a third pitch geometry ranging from 0.5 mm to 1.0 mm. In an aspect, the solder balls 512a and 512b may include a fourth pitch geometry lesser than the third pitch geometry ranging from 0.3 mm to 0.5 mm. In addition, the solder balls 511a and 511b having a larger diameter are configured to facilitate power delivery from the first type PCB 502 to the first and second devices 505 and 504, respectively.

As shown in FIG. 5A, a top view of the semiconductor assembly 500 shows the Type-IV PCB 503 embedded in the recess 510 in the Type-III PCB 502. The first device 505 abridges the Type-III PCB 502 and the Type-IV PCB 503 and is coupled by signal connection 509 in the Type-IV PCB 503 to the second device 504, which also abridges the Type-III PCB 502 and the Type-IV PCB 503. The several passive components 506, two power components 513, and two connectors 508 are also shown. Although not shown, it should be understood that other components/devices may be provided to complete the semiconductor assembly 500.

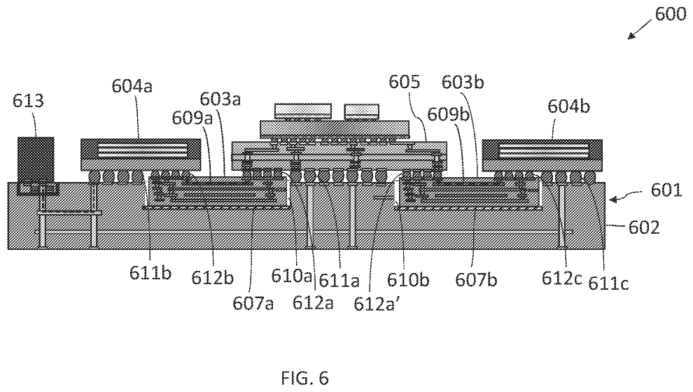

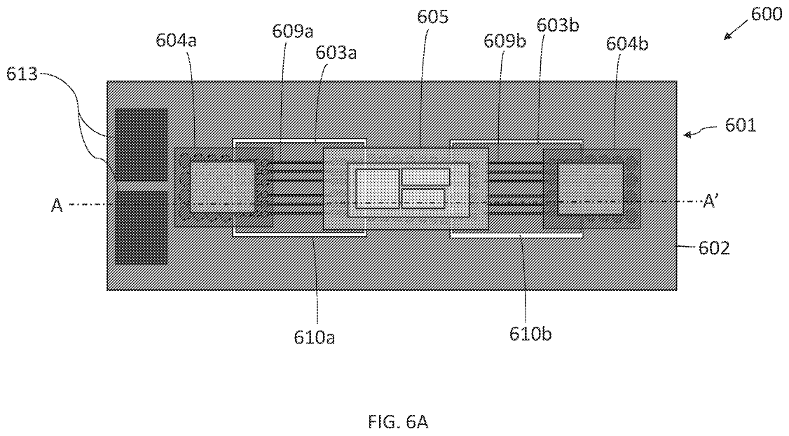

FIGS. 6 and 6A show cross-section and top views, respectively, of another exemplary semiconductor assembly 600 with a printed circuit board with two Type IV printed circuit boards embedded in their respective recesses formed in a Type III printed circuit board according to an aspect of the present disclosure. FIG. 6 shows a cross-section view along the section line A-A′ shown in FIG. 6A. In this aspect, the composite or heterogeneous printed circuit board 601 includes a first section of first type PCB 602 and second and third sections of second type PCB 603a and 603b. The first type PCB 602 may be a Type-III PCB as the mainboard or motherboard and the second and third sections 603a and 603b of a second type PCB may be a Type-IV PCB, which may be an embeddable section or translator module placed in recesses 610a and 610b, respectively. In an aspect, the recesses 610a and 610b may have depths that allow the second type PCBs 603a and 603b to be co-planar with the first type PCB 602, or as shown in FIG. 6, positions the second type PCBs 603a and 603b to be elevated higher than a top surface of the first type PCB 602 forming steps therebetween.

In an aspect, the first type PCB 602 motherboard may include a first metal layer stack-up having a plurality of routing layers extending between the top surface and a bottom surface of the first type PCB 602, and the routing layers are coupled through a plurality of plated through hole (PTH) vias extending from the top surface through to the bottom surface, as well as other conventional features of Type-III PCBs. In an aspect, the first PCB 602 may have a thickness ranging from approximately 0.8 mm to 1 mm.

In another aspect, the second type PCBs 603a and 603b may be a molded interconnect layer or substrate, which also provides embedded copper trace technology having finer lines and spaces for high density interconnects and a smaller form factor. In a further aspect, the second type PCB may be made of a material such as bismaleimide triazine (BT) epoxy layer with reinforced fiber glasses or one or more layers of epoxy mold compound composites.

In an aspect, the second type PCBs 603a and 603b may include a metal layer stack-up having a plurality of routing layers extending between a top surface and a bottom surface of the second type PCBs 603a and 603b, respectively, and the routing layers are coupled through a plurality of vertical micro-vias or lasered vias, as well as other conventional features of Type-IV PCBs. In a further aspect, the second type PCBs 603a and 603b may have thicknesses ranging approximately from 100 μm to 600 μm. In an aspect, adhesive materials 607a and 607b may be applied at bottom surfaces of the recesses 610a and 610b, respectively, to attach/bond the second type PCBs 603a and 603b to the first type PCB 602, respectively.

As shown in FIG. 6, the semiconductor assembly 600 may have a plurality of devices, which may include a first device 605 (e.g., a semiconductor package having a central processing unit (CPU), system on chip (SOC), controller hub chiplets, a radio frequency integrated circuit (RFIC), a deep learning processor (DLP), a graphic processing unit (GPU), a neural network processor (NNP) and/or an I/O tile), a second device 604a and third device 604b (e.g., dynamic random access memory (DRAM) devices such as 5^{th} Generation Double Data Rate (DDR5) memory devices, 6^{th} Generation Double Data Rate (DDR6) memory devices, 5^{th} Generation Low-Power Double Data Rate (LPDDR5) memory devices, or 6^{th} Generation Low-Power Double Data Rate (LPDDR6) memory devices), and power components 613 (e.g., voltage regulators). Although not shown, it should be understood that other components/devices may be provided to complete the semiconductor assembly 600. In an aspect, the first device 605, the second device 604a, and the third device 604b, respectively, may be configured to abridge the sections 602, 603a, and 603b of the composite printed circuit board 601.

In another aspect, as shown in FIG. 6, the first device 605 may have solder balls 611a for bonding and coupling with the Type-III PCB 602 and solder balls 612a for bonding and coupling with the Type-IV PCB 603a and solder balls 612a′ for bonding and coupling with the Type-IV PCB 603b. The second device 604a may have solder balls 611b for bonding and coupling with the Type-III PCB 602 and solder balls 612b for bonding and coupling with the Type-IV PCB 603a. The third device 604b may have solder balls 611c for bonding and coupling with the Type-III PCB 602 and solder balls 612c for bonding and coupling with the Type-IV PCB 603b. As also shown in FIG. 6, by way of the solder balls 612a and 612b, respectively, the first device 605 may be coupled to the second device 604a by a signal connection 609a in the Type-IV PCB 603a, and by way of the solder balls 612a′ and 612c, respectively, the first device 605 may be coupled to the third device 604b by a signal connection 609b in the Type-IV PCB 603b.

In an aspect, the solder balls 611a, 611b, and 611c, with identical diameters ranging from approximately 250 μm to 700 μm, will be larger than solder balls 612a, 612a′, 612b, and 612c, with identical diameters ranging from approximately 100 μm to 250 μm, when the Type-IV PCBs 603a and 603b are positioned elevated higher than the Type-III PCB 602. In an aspect, the solder balls 611a, 611b and 611c may include a fifth pitch geometry ranging from mm to 1.0 mm. In an aspect, the solder balls 612a, 612a′, 612b and 612c may include a sixth pitch geometry lesser than the fifth pitch geometry ranging from 0.3 mm to 0.5 mm. In addition, the solder balls 611a, 611b, and 611c having a larger diameter are configured to facilitate power delivery from the first type PCB 602 to the first, second, and third devices 605, 604a, and 604b, respectively.

As shown in FIG. 6A, a top view of the semiconductor assembly 600 shows the Type-IV PCBs 603a and 603b embedded in the recess 610a and 610b, respectively, in the Type-III PCB 602. The first device 605 abridges the Type-III PCB 602 and the two Type-IV PCBs 603a and 603b. The first device 605 is coupled by signal connection 609a in the Type-IV PCB 603a to the second device 604a, which also abridges the Type-III PCB 602 and the Type-IV PCB 603a, and is coupled by signal connection 609b in the Type-IV PCB 603b to the third device 604b, which also abridges the Type-III PCB 602 and the Type-IV PCB 603b. The two power components 613 are also shown.

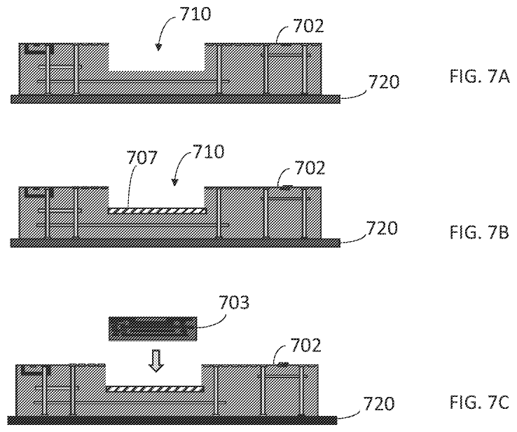

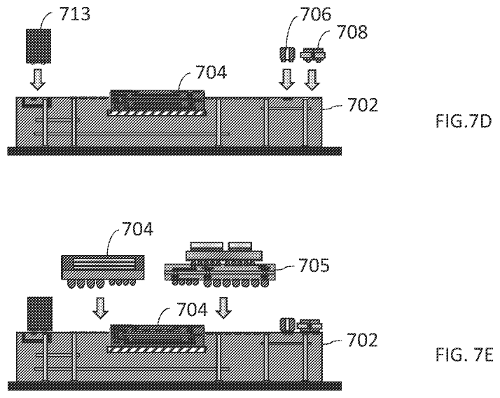

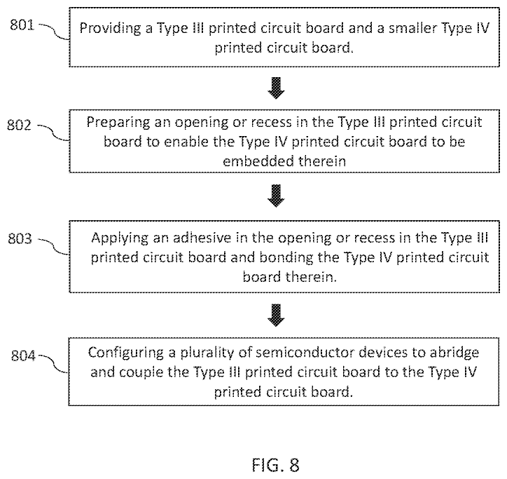

FIGS. 7A through 7E show exemplary method steps for embedding a Type-IV PCB in a recess formed in a Type-III PCB to form a composite printed circuit board according to another aspect of the present disclosure. As shown in FIG. 7A, a Type III PCB 702 is positioned on working platform 720, and a portion of the Type-III PCB 702 is removed to form a recess 710. The process to remove the portion of the Type-III PCB 702 to form the recess 710 may include conventional methods such as mechanical sawing, laser etching, or other etching processes. The depth of the recess 710 will be determined by the desired level of the embedded Type-IV PCB relative to the level of the Type-III PCB motherboard.

As shown in FIG. 7B, an adhesive material 707 may be placed in the recess 710 by a conventional method, e.g., lamination or hot press process, and as shown in FIG. 7C, an appropriately configured section of Type-IV PCB 703 may be positioned in the recess 710 and attached/bonded to the Type-III PCB 702. The attachment process of the Type-IV PCB 703 to the Type-III PCB 702 may include conventional methods such as a hot press and curing process, or other bonding processes.

As shown in FIGS. 7D and 7E, the attachment of a plurality of the devices/components to form a semiconductor assembly may be performed in a two-step process. It should be understood that a one-step process may also be used to perform the attachment of the devices/components, especially when the first and second type PCBs are co-planar.

In the aspect shown in FIG. 7D, a first surface mounting step may be performed to attached devices/components to the Type-III PCB 702; for example, a passive device 706 and a voltage regulator 713, and a connector 708. The surface mounting technology employed to attach these devices/components to the Type-III PCB 702 may include conventional methods such as reflowing soldering, thermal compression bonding, or other bonding processes.

As shown in FIG. 7E, a second surface mounting step may be performed to attached devices that abridge or overlap both the Type-III PCB 702 and the Type-IV PCB 703; for example, a first device 705 and a second device 704. The surface mounting technology employed to attach these devices to the Type-III PCB 702 and the Type-IV PCB 703 may include conventional methods such as reflowing soldering, thermal compression bonding, or other bonding processes.

FIG. 8 shows a simplified flow diagram for an exemplary method according to an aspect of the present disclosure.

The operation 801 may be directed to providing a Type III printed circuit board and a smaller Type IV printed circuit board.

The operation 802 may be directed to preparing an opening or recess in the Type III printed circuit board to enable the Type IV printed circuit board to be embedded therein.

The operation 803 may be directed to applying an adhesive in the opening or recess in the Type III printed circuit board and bonding the Type IV printed circuit board therein.

The operation 804 may be directed to configuring a plurality of semiconductor devices to abridge and couple the Type III printed circuit board to the Type IV printed circuit board.

It will be understood that any property described herein for a specific tool may also hold for any tool or system described herein. It will also be understood that any property described herein for a specific method may hold for any of the methods described herein. Furthermore, it will be understood that for any tool, system, or method described herein, not necessarily all the components or operations described will be enclosed in the tool, system, or method, but only some (but not all) components or operations may be enclosed.

To more readily understand and put into practical effect the present composite printed circuit board, they will now be described by way of examples. For the sake of brevity, duplicate descriptions of features and properties may be omitted.

### EXAMPLES

Example 1 provides a printed circuit board including a composite upper surface including a first section of a first-type of printed circuit board and a second section of a second-type of printed circuit board, for which the first section of the first-type of printed circuit board and the second section of the second-type of printed circuit board are coupled, respectively, to at least one device that is configured to abridge the first and second sections of the composite upper surface.

Example 2 may include the printed circuit board of example 1 and/or any other example disclosed herein, further including the second-type of printed circuit board configured to be embedded in the first-type of printed circuit board.

Example 3 may include the printed circuit board of example 2 and/or any other example disclosed herein, for which the first-type of printed circuit board is configured with an opening and the second-type of printed circuit board is embedded in the opening.

Example 4 may include the printed circuit board of example 2 and/or any other example disclosed herein, for which the first-type of printed circuit board is configured with a recess and the second-type of printed circuit board is embedded in the recess.

Example 5 may include the printed circuit board of example 1 and/or any other example disclosed herein, further including the first section of the first-type of printed circuit board and the second section of the second-type of printed circuit board configured to be co-planar or configured with the second section of the second-type of printed circuit board elevated to form a step between the first section of the first-type of printed circuit board.

Example 6 may include the printed circuit board of example 1 and/or any other example disclosed herein, for which the first-type of printed circuit board further includes a Type III printed circuit board.

Example 7 may include the printed circuit board of example 1 and/or any other example disclosed herein, for which the second-type of printed circuit board further includes a Type IV printed circuit board or a molded interconnect bridge.

Example 8 may include the printed circuit board of example 1 and/or any other example disclosed herein, for which the composite upper surface further includes an additional second section of the second-type of printed circuit board, for which the additional second section is configured to be coupled to the at least one device that abridges the first section and the additional second section.

Example 9 provides a semiconductor assembly including a composite printed circuit board having a first section of a first-type of printed circuit board and a second section of a second-type of printed circuit board, for which the second section of the second-type of printed circuit board is embedded in the first section of the first-type of printed circuit board, and at least one device configured to abridge the first and second sections of the composite printed circuit board.

Example 10 may include the semiconductor assembly of example 9 and/or any other example disclosed herein, for which the at least one device includes a processor.

Example 11 may include the semiconductor assembly of example 10 and/or any other example disclosed herein, further including at least one memory device positioned on and coupled to the second-type of printed circuit board, for which the memory device is coupled to the processor.

Example 12 may include the semiconductor assembly of example 9 and/or any other example disclosed herein, further including a plurality of zero ohm resistors abridging the first section and the second section.

Example 13 may include the semiconductor assembly of example 9 and/or any other example disclosed herein, for which the first type printed circuit board comprises a Type III printed circuit board, and for which the second type printed circuit board comprises a Type IV printed circuit board or a molded interconnect bridge.

Example 14 may include the semiconductor assembly of example 9 and/or any other example disclosed herein, for which the at least one device further including a plurality of first solder balls coupled to the first section of the composite printed circuit board, and a plurality of second solder balls coupled to the second section of the composite printed circuit board, for which the first solder balls are larger than the second solder balls.

Example 15 may include the semiconductor assembly of example 11 and/or any other example disclosed herein, further including a solder ball array coupled to the composite printed circuit board, with the solder ball array being configured with a first plurality of solder balls connecting to the memory device and positioned separated from a second plurality of solder balls providing other signal connections.

Example 16 may include the semiconductor assembly of example 10 and/or any other example disclosed herein, for which the composite printed circuit board further includes an additional second section of the second type printed circuit board, with the additional second section being configured to be embedded in the first section of the first-type of printed circuit board, and for which the semiconductor assembly further includes the processor being configured to abridge the first section, the second section, and the additional second section.

Example 17 provides a method including providing a first-type of printed circuit board and a second-type of printed circuit board and forming a composite printed circuit board by embedding the second-type of printed circuit board in the first-type of printed circuit board to form a composite upper surface.

Example 18 may include the method of example 17 and/or any other example disclosed herein, further including forming an opening or a recess in the first type printed circuit board, for which the second-type of printed circuit board is embedded in the opening or the recess in the first-type of printed circuit board, and bonding the second-type of printed circuit board to the first-type of printed circuit board to form the composite printed circuit board.

Example 19 may include the method of example 18 and/or any other example disclosed herein, for which forming the composite printed circuit board further including providing an additional second-type of printed circuit board, forming an additional opening or recess in the first type printed circuit board, for which the additional second-type of printed circuit board is configured to be embedded in the additional opening or the additional recess in the first-type of printed circuit board, and
bonding the additional second-type of printed circuit board to the first-type of printed circuit board to form the composite printed circuit board.

Example 20 may include the method of example 17 and/or any other example disclosed herein, further including surfacing mounting a plurality of devices on the composite printed circuit board in a single operation to form a semiconductor assembly, for which at least one of the plurality of devices is configured to abridge the first-type of printed circuit board and the second-type of printed circuit board.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

The term “coupled” (or “connected”) herein may be understood as electrically coupled or as mechanically coupled, e.g., attached or fixed or attached, or just in contact without any fixation, and it will be understood that both direct coupling or indirect coupling (in other words: coupling without direct contact) may be provided.

The terms “and” and “or” herein may be understood to mean “and/or” as including either or both of two stated possibilities.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

What is claimed is:

1. A printed circuit board comprising:
a composite upper surface comprising a first section of a first-type of printed circuit board and a second section of a second-type of printed circuit board,
wherein the first section of the first-type of printed circuit board and the second section of the second-type of printed circuit board are coupled, respectively, to at least one device that is configured to abridge the first and second sections of the composite upper surface.

2. The print circuit board of claim 1, further comprising the second-type of printed circuit board configured to be embedded in the first-type of printed circuit board.

3. The print circuit board of claim 2, wherein the first-type of printed circuit board is configured with an opening and the second-type of printed circuit board is embedded in the opening.

4. The print circuit board of claim 2, wherein the first-type of printed circuit board is configured with a recess and the second-type of printed circuit board is embedded in the recess.

5. The print circuit board of claim 1, further comprising the first section of the first-type of printed circuit board and the second section of the second-type of printed circuit board configured to be co-planar or configured with the second section of the second-type of printed circuit board elevated to form a step between the first section of the first-type of printed circuit board.

6. The print circuit board of claim 1, wherein the first-type of printed circuit board further comprises a Type III printed circuit board.

7. The print circuit board of claim 1, wherein the second-type of printed circuit board further comprises a Type IV printed circuit board or a molded interconnect bridge.

8. The print circuit board of claim 1, wherein the composite upper surface further comprises an additional second section of the second-type of printed circuit board, wherein the additional second section is configured to be coupled to the at least one device that abridges the first section and the additional second section.

9. A semiconductor assembly comprising:
a composite printed circuit board comprising a first section of a first-type of printed circuit board and a second section of a second-type of printed circuit board, wherein the second section of the second-type of printed circuit board is embedded in the first section of the first-type of printed circuit board; and
at least one device configured to abridge the first and second sections of the composite printed circuit board.

10. The semiconductor assembly of claim 9, wherein the at least one device comprising a processor.

11. The semiconductor assembly of claim 10, further comprising at least one memory device positioned on and coupled to the second-type of printed circuit board, wherein the memory device is coupled to the processor.

12. The semiconductor assembly of claim 9, further comprising a plurality of zero ohm resistors abridging the first section and the second section.

13. The semiconductor assembly of claim 9, wherein the first-type of printed circuit board comprises a Type III printed circuit board; and
wherein the second-type of printed circuit board comprises a Type IV printed circuit board or a molded interconnect bridge.

14. The semiconductor assembly of claim 9, wherein the at least one device further comprising:
a plurality of first solder balls coupled to the first section of the composite printed circuit board; and
a plurality of second solder balls coupled to the second section of the composite printed circuit board, wherein the first solder balls are larger than the second solder balls.

15. The semiconductor assembly of claim 11, further comprising a solder ball array coupled to the composite printed circuit board, the solder ball array being configured with a first plurality of solder balls connecting to the memory device and positioned separated from a second plurality of solder balls providing other signal connections.

16. The semiconductor assembly of claim 10, wherein the composite printed circuit board further comprises an additional second section of the second type printed circuit board, the additional second section being configured to be embedded in the first section of the first-type of printed circuit board; and wherein the semiconductor assembly further comprises the processor being configured to abridge the first section, the second section, and the additional second section.

17. A method comprising:
providing a first-type of printed circuit board;
providing a second-type of printed circuit board; and
forming a composite printed circuit board by embedding the second-type of printed circuit board in the first-type of printed circuit board to form a composite upper surface.

18. The method of claim 17, further comprising:
forming an opening or a recess in the first type printed circuit board, wherein the second-type of printed circuit board is embedded in the opening or the recess in the first-type of printed circuit board; and
bonding the second-type of printed circuit board to the first-type of printed circuit board to form the composite printed circuit board.

19. The method of claim 18, wherein forming the composite printed circuit board further comprising:
providing an additional second-type of printed circuit board;
forming an additional opening or an additional recess in the first type printed circuit board, wherein the additional second-type of printed circuit board is configured to be embedded in the additional opening or the additional recess in the first-type of printed circuit board; and
bonding the additional second-type of printed circuit board to the first-type of printed circuit board to form the composite printed circuit board.

20. The method of claim 17, further comprising:
surfacing mounting a plurality of devices on the composite printed circuit board in a single operation to form a semiconductor assembly, wherein at least one of the plurality of devices is configured to abridge the first-type of printed circuit board and the second-type of printed circuit board.
